(19) United States
(12) Patent Application Publication
(10) Pub. No.: US 2021/0271003 A1
(43) Pub. Date: Sep. 2, 2021

(54) OPTICAL ELEMENT INCLULDING MICROLENS ARRAY

(71) Applicant: 3M INNOVATIVE PROPERTIES COMPANY, St. Paul, MN (US)

(72) Inventors: Zhaohui Yang, North Oaks, MN (US); Przemyslaw P. Markowicz, Woodbury, MN (US); John A. Wheatley, Stillwater, MN (US); Qingbing Wang, Campbell, CA (US); Mark A. Roehrig, Stillwater, MN (US); Tri D. Pham, Woodbury, MN (US); Serena L. Schleusner, Roberts, WI (US); Kenneth A.P. Meyer, Eagan, MN (US); Levent Biyikli, Cedar Park, TX (US); Thomas V. Weigman, Stillwater, MN (US)

(21) Appl. No.: 17/259,299

(22) PCT Filed: Aug. 8, 2019
(86) PCT No.: PCT/IB2019/056781

§ 371 Date: Jan. 11, 2021

Related U.S. Application Data
(60) Provisional application No. 62/764,702, filed on Aug. 15, 2018.
(60) Provisional application No. 62/752,634, filed on Oct. 30, 2018.

(51) Int. Cl. G02B 3/00; G02B 5/28

(52) U.S. Cl. CPC G02B 3/0056; G02B 3/0062; G06K 9/00046; G02B 3/0075; G02B 2207/123; G02B 5/285

(57) ABSTRACT

An optical element including an array of microlenses, a pinhole mask, and a wavelength selective filter is described. The pinhole mask includes an array of pinholes with each pinhole in the array of pinholes aligned with a microlens in the first array of microlenses. The wavelength selective filter is adapted to transmit a first light ray having a first wavelength and transmitted from a first microlens in the array of microlenses through a first pinhole in the array of pinholes aligned with the first microlens, and to attenuate a second light ray having the first wavelength and transmitted from the first microlens through a second pinhole in the array of pinholes aligned with a second microlens in the first array of microlenses adjacent to the first microlens.

### BACKGROUND

Display devices may include a fingerprint sensor which detects light reflected by the fingerprint. An image recognition system may include a microlens array, a detector array, and a pinhole array.

### SUMMARY

In some aspects of the present description, an optical element including a first array of microlenses, a pinhole mask, and a wavelength selective filter is provided. The pinhole mask includes an array of pinholes where each pinhole in the array of pinholes aligned with a microlens in the first array of microlenses. The wavelength selective filter is adapted to transmit a first light ray having a first wavelength and transmitted from a first microlens in the first array of microlenses through a first pinhole in the array of pinholes aligned with the first microlens, and attenuate a second light ray having the first wavelength and transmitted from the first microlens through a second pinhole in the array of pinholes aligned with a second microlens in the first array of microlenses adjacent to the first microlens.

In some aspects of the present description, an optical element including a first layer having opposing first and second major surfaces where the first major surface includes a first array of microlenses, a second layer comprising an array of pinholes where each pinhole in the array of pinholes is disposed to receive light from a corresponding microlens in the first array of microlenses, and a multilayer optical film adjacent at least one of the first and second layers is provided. The multilayer optical film has, at normal incidence, a pass band extending over a predetermined wavelength range and having a long wavelength band edge wavelength at normal incidence in a visible or near-infrared wavelength range.

In some aspects of the present description, an optical element including a first layer having opposing first and second major surfaces where the first major surface includes a first array of microlenses, a second layer comprising an array of pinholes where each pinhole in the array of pinholes disposed to receive light from a corresponding microlens in the first array of microlenses, and an optional third layer having opposing first and second major surface where the first major surface of the optional third layer disposed on the first major surface of the first layer and the first major surface but not the second major surface of the optional third layer has a shape substantially conforming to the first major surface of the first layer is provided. At least one of the first layer or optional third layer includes wavelength selective absorptive material dispersed throughout the layer and providing an absorption band having an absorption for normally incident light in a predetermined first wavelength range of at least 50%.

In some aspects of the present description, an optical element including a first array of microlenses, and a wavelength selective layer including an array of pinholes in or through the wavelength selective layer where each pinhole in the array of pinholes is aligned with a microlens in the first array of microlenses is provided. For at least one polarization state, regions of the wavelength selective layer between adjacent pinholes transmit at least 60% of normally incident light in a predetermined first wavelength range and blocks at least 60% of normally incident light in a predetermined second wavelength range.

In some aspects of the present description, an optical element including a first layer comprising opposing first and second major surfaces is provided. The first major surface includes a first array of microlenses where each microlens is concave toward the second major surface, and an array of posts where each post in at least a majority of posts in the array of posts positioned between two or more adjacent microlenses in the first array of microlenses and extend above the two or more adjacent microlenses in a direction away from the second major surface.

In some aspects of the present description, an optical element including at least one array of microlenses and at least one array of pinholes is provided. In some embodiments, each array of microlenses is aligned in a predetermined way with an array of pinholes. In some embodiments, the optical element includes a wavelength selective filter in optical communication with the at least one array of microlenses and the at least one array of pinholes. In some embodiments, the optical element includes an array of posts where each post in at least a majority of the array of posts is positioned between two or more adjacent microlenses.

In some aspects of the present description, an electronic device including an optical element described herein is provided.

### BRIEF DESCRIPTION OF THE DRAWINGS

FIGS. 1-4 are schematic cross-sectional views of optical elements including microlenses;

FIG. 5 is a schematic cross-sectional view of an interference filter;

FIG. 6A is a schematic plot of transmittance versus wavelength at normal incidence for an optically absorptive filter and a multilayer optical film;

FIG. 6B is a schematic plot of transmittance versus wavelength at an oblique angle of incidence for the optically absorptive filter and multilayer optical film of FIG. 6A;

FIG. 6C is a schematic plot of an emission spectrum of a light source superimposed on the transmittance of a multilayer optical film at normal incidence;

FIG. 7 is a schematic cross-sectional view of an optical element including two arrays of microlenses;

FIGS. 8-10 are schematic cross-sectional views of optical elements schematically illustrating alignment of microlenses with pinholes;

FIG. 11 is a schematic illustration of an electronic device including an optical element adjacent to a sensor;

FIG. 12 is a schematic illustration of an electronic display device including an optical element disposed between a display panel and an optical sensor;

FIG. 13A is a schematic cross-sectional view of an optical element including an array of microlenses and an array of posts;

FIG. 13B is a schematic cross-sectional view of an optical element including an array of microlenses and an array of posts attached to an adjacent layer;

FIG. 14 is a schematic top view of an optical element including a square array of microlenses;

FIG. 15 is a schematic top view of an optical element including a square array of microlenses and a square array of posts;

FIG. 16 is a schematic top view of a portion of a hexagonal array of microlenses and a portion of a hexagonal array of posts;

FIGS. 17A-17D are schematic top views of pinholes;

FIGS. 18A-18B are schematic top views of microlenses;

FIG. 19 is a schematic cross-sectional view of a barrier layer disposed on another layer;

FIG. 20 is a schematic cross-sectional view of an optical element including an array of microlenses and a multilayer optical film;

FIG. 21 is a schematic top view of an optical element including first and second regions; and

FIGS. 22-23 are schematic cross-sectional views of first and second mask layers separated by spacer layers.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

It may be desired to use a collimating optical element disposed to transmit light to an optical sensor in order to improve the optical sensor's resolution. Suitable collimating optical elements include a microlens array and a pinhole mask where the microlenses have a focus at the pinholes. It has traditionally been desired to have an air gap at the surface of the microlens array in order to maximize the index contrast across the surface of the microlenses. When an air gap is not present, the index contrast between the microlens array and an adjacent layer is reduced, and this can allow a portion of light incident on a microlens to pass through a pinhole aligned with an adjacent microlens which would have been blocked by the pinhole layer if an air gap were present. According to some embodiments of the present description, an optical filter is provided that allows light to pass through a pinhole aligned with a microlens but not through an adjacent pinhole due to a shift in band edge with an increased angle of incidence to the optical filter at the adjacent pinhole. This allows the microlens array to be immersed in an adhesive layer without substantially sacrificing the collimation provided by the aligned arrays of microlenses and pinholes. In some embodiments, a layer including an array of microlenses also includes an array of posts which allows the layer to be bonded to an adhesive layer through the posts while leaving an air gap above the microlenses. This allows the layer to be bonded to an adjacent layer while maintaining the index contrast across the microlenses and so the bonding does not sacrifice the collimation provided by the aligned arrays of microlenses and pinholes.

The optical elements described herein are useful in a variety of electronic devices including electronic display devices, for example. Various devices in which an optical element of the present description can be included are described in U.S. Pat. Appl. No. 2007/0109438 (Duparre et al.), 2008/0005005 (He et al.), and 2018/00129069 (Chung et al.), for example.

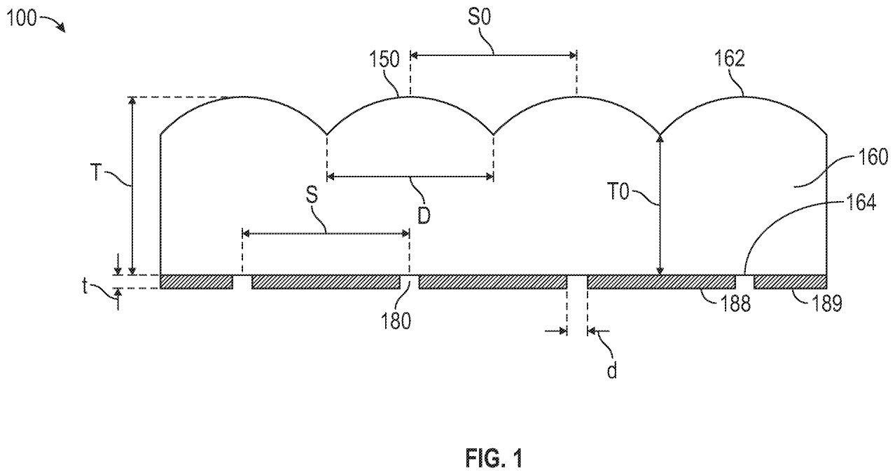

FIG. 1 is a schematic cross-sectional view of an optical element 100 including an array of microlenses 150 and a pinhole mask 189 including an array of pinholes 180. A pinhole mask substantially blocks (e.g., blocks at least 60% of light by absorption, reflection, or a combination thereof) light incident on the mask between pinholes for at least one wavelength and for at least one polarization state. In some embodiments, the pinhole mask 189 includes pinholes in a substantially optically opaque material or includes pinholes in a wavelength selective filter, for example. A substantially optically opaque material or layer is a material or layer having a transmission for normally incident unpolarized light in a predetermined wavelength range in the near-ultraviolet (e.g., less than 400 nm and at least 350 nm), visible (e.g., 400 nm to 700 nm) and/or infrared (greater than 700 nm and no more than 2500 nm) of less than 10%. In some embodiments, the predetermined wavelength range extends at least from 400 nm to 700 nm. The transmission may depend on material properties (e.g., absorbance) and material thickness. In some embodiments, the pinhole mask 189 is substantially optically opaque between adjacent pinholes in the array of pinholes 180. In some embodiments, the pinhole mask 189 is or includes a wavelength selective layer where the array of pinholes 180 includes pinholes in or through the wavelength selective layer. In some embodiments, for at least one polarization state (and in some embodiments, for each of two orthogonal polarization states), the wavelength selective layer has regions between adjacent pinholes that transmit at least 60% of normally incident light in a predetermined first wavelength range (e.g., a near ultraviolet, a visible, or a near infrared range) and blocks at least 60% of normally incident light in a predetermined second wavelength range (e.g., a different near ultraviolet, a visible, or a near infrared range). In some embodiments, the wavelength selective layer has regions between adjacent pinholes that transmit at least 60% of normally incident unpolarized light in a predetermined first wavelength range and blocks at least 60% of normally incident unpolarized light in a predetermined second wavelength range. The wavelength selective layer may be a wavelength selective mirror or a wavelength selective reflective polarizer, for example. In some embodiments, the wavelength selective layer is substantially optically opaque in at least one wavelength range. Transmittance, reflectance and absorbance can be understood to refer to transmittance, reflectance and absorbance, respectively, for unpolarized light unless indicated otherwise (e.g., by referencing a polarization state) or it is otherwise clear from the context.

A substantially optically opaque material may be used to filter light in a predetermined wavelength range which may be the entire visible range, for example. A wavelength selective layer may be used to filter light in the second predetermined wavelength range but not in the first predetermined wavelength range. One of the first and second predetermined wavelength ranges may be a visible range and the other of the first and second predetermined wavelength ranges may be a near-infrared range, for example. Visible light refers to light having wavelengths in a range of 400 nm to 700 nm, unless indicated differently. Near-infrared refers to light having wavelengths greater than 700 nm and up to 2500 nm, unless indicated differently.

A pinhole can be a physical pinhole or an optical pinhole, for example. A physical pinhole in an optically opaque material or in a wavelength selective layer, for example, is an opening through the material or layer that allows light from a corresponding microlens to pass through. The size of the opening is substantially smaller (e.g., at least a factor of 5, or at least a factor of 10, or at least a factor of 20 smaller) than an average diameter D of the microlenses and/or substantially smaller than an average focal distance of the microlenses. An optical pinhole in a layer or film is a region in the layer or film having a geometry similar to a physical pinhole (e.g., a size of the pinhole is substantially smaller than a diameter or a focal length of the corresponding microlens) where the material of the layer or film has been altered to allow light that would have otherwise been blocked to be transmitted. For example, optical pinholes in a birefringent multilayer optical film can be created by locally heating the optical film to reduce or eliminate birefringence in the pinhole regions so that the pinhole regions become substantially more optically transmissive for wavelengths in at least a portion of a reflection band of the optical film than other regions of the optical film. In some embodiments, the multilayer optical film physically extends continuously across the pinhole. Spatially tailoring optical properties of multilayer optical films is generally described in U.S. Pat. No. 9,575,233 (Merrill et al.), for example. In some embodiments, a pinhole in a multilayer pinhole mask, for example, includes pinholes in one or more layers of the mask but not necessarily in all the layers. For example, a multilayer pinhole mask may include first and second mask layers with a spacer layer therebetween (and optionally additional spaced apart mask layers). The first and second mask layers may include aligned arrays of physical or optical pinholes. In this case, each pair of aligned pinholes along with a region of the spacer layer between the aligned pinholes providing an optical path between the aligned pinholes can be considered to be a pinhole in the multilayer mask whether or not the spacer layer includes a physical pinhole extending between the first and second pinholes.

A microlens is a lens having at least one lateral dimension (e.g., diameter) less than 1 mm. In some embodiments, the average diameter D of the microlenses is in a range of 5 micrometers to 1000 micrometers.

In some embodiments, the microlenses are curved about two orthogonal directions and the pinholes have largest lateral dimensions in each of two orthogonal directions substantially smaller than corresponding lateral dimensions of the microlens. In other embodiments, the microlenses are lenticular microlenses and the pinholes are slits (optically or physically) having a width substantially smaller than a width of the lenticular microlenses and having a length extending in a direction along the length of the lenticular microlenses. In some embodiments, two such optical elements with lenticular microlenses extending in different directions may be used in a sensor device or one such optical element may be combined with a louver film having louvers extending in a direction different from that of the lenticular microlenses in an optical sensor device.

Optical element 100 includes a first layer 160 having opposing first and second major surfaces 162 and 164 and includes a second layer 188 disposed on the second major surface 164. The first major surface 162 includes the array of microlenses 150. The second layer 188 includes the pinhole mask 189 and the array of pinholes 180. The second layer 188 may include the pinhole mask 189 and an additional coating or layer, for example, or the second layer 188 may consist of or consist essentially of the pinhole mask 189. The first layer 160 has a thickness T and the second layer 188 has a thickness t which is also the thickness of the pinhole mask 189 in the illustrated embodiment. In some embodiments, t/T is less than 0.5, or less than 0.2, or less than 0.1, or less than 0.05, or less than 0.02, or less than 0.01. For example, in some embodiments, t is in a range of 0.01 to 0.2 micrometers and T is in a range of 10 to 200 micrometers. A larger thickness of the pinhole mask may be chosen to reduce cross-talk (light from one microlens incident on a pinhole aligned with a different microlens), for example, or a smaller thickness of the pinhole mask may be chosen to increase the light transmitted through the pinholes. In either case, an optical filter may be included to reduce or further reduce cross-talk as described further elsewhere herein. In some embodiments, the array of pinholes has an average center to center distance between adjacent pinholes of S and 0.1≤S/T≤2. In some embodiments, the diameter D is approximately equal (e.g., within 10%) to the distance S. In some embodiments, the array of microlenses 150 has an average center to center distance between adjacent microlenses of S0 which may be equal or approximately equal (e.g., within±10% or within±5%) to the distance S. A distance between the array of microlenses 150 and the second layer 188 or the pinhole mask 189 is T0 in the illustrated embodiment. In some embodiments, the array of pinholes 180 has an average pinhole diameter d which may be substantially smaller than T0 (e.g., a factor of at least 4, or at least 8, or at least 10 times). In some embodiments, the pinhole mask 189 or the second layer 188 may be sufficiently thick to provide a reduction in crosstalk (e.g., light incident on one microlens passing through a pinhole aligned with another microlens). The pinhole mask 189 or the second layer 188 may be a single layer having a desired thickness or may include spaced apart mask layers as described further elsewhere herein. In some embodiments, the thickness t of the pinhole mask 189 or the second layer 188 is no less than 0.1 T0*d/S0. In some embodiments, 10 T0*d/S0≥ts≥0.1 T0*d/S0, or 8 T0*d/S0≥ts≥0.2 T0*d/S0, or 6 T0*d/S0≥ts≥0.4 T0*d/S0, 4 T0*d/S0≥ts≥0.5 T0*d/S0. In some embodiments, the pinhole mask 189 or second layer 188 may be adapted to transmit normally incident light. In some embodiments, the pinhole mask 189 or second layer 188 may be adapted to transmit obliquely incident light at a predetermined oblique angle of incidence as described further elsewhere herein.

A second layer may be disposed on a second major surface of a first layer having opposing first and second major surfaces by being directly disposed on the second major surface or being indirectly disposed on the second major surface through one or more intervening layers with the second major surface of the first layer disposed between the first major surface of the first layer and the second layer. Adjacent first and second layers may be immediately adjacent or the adjacent first and second layers may be separated by one or more intervening layers.

A layer may be a monolayer or may include sublayers bonded to one another. In some embodiments, the first layer 160 is monolithic or unitary. In some embodiments, the first layer 160 includes one or more sublayers bonded to one another. In some embodiments, the first layer 160 includes a polymer film substrate and a monolithic or unitary layer including the microlenses 150 disposed on the substrate.

The optical element 100 can be made by micro-replicating the array of microlenses using a cast and ultra-violet (UV) cure process, for example, where a resin is cast on a substrate and cured in contact with a replication tool surface as generally described in U.S. Pat. No. 5,175,030 (Lu et al.), U.S. Pat. No. 5,183,597 (Lu) and U.S. Pat. No. 9,919,339 (Johnson et al.), and in U.S. Pat. Appl. Publ. No. 2012/0064296 (Walker, JR. et al), for example. The pinhole mask 189 can then be formed by coating a substantially opaque material, for example, onto to second major surface 164. For example, the substantially opaque material may be 100 nm to 150 nm thick aluminum and may be coated using standard magnetron sputtering, for example. The pinholes 180 can then be formed by laser ablation through the microlenses, for example. Suitable lasers include fiber lasers such as a 40 W pulsed fiber laser operating a wavelength of 1070 nm, for example. In some embodiments, the pinhole mask 189 is formed by applying a wavelength selective multilayer optical film onto to second major surface 164. Physical or optical pinholes can then be formed in the optical film by irradiating with a laser through the microlenses. An absorption overcoat can optionally be applied to the optical film to increase the absorption of energy from the laser. Creating apertures in a layer using a laser through a microlens array is generally described in US2007/0258149 (Gardner et al.), for example.

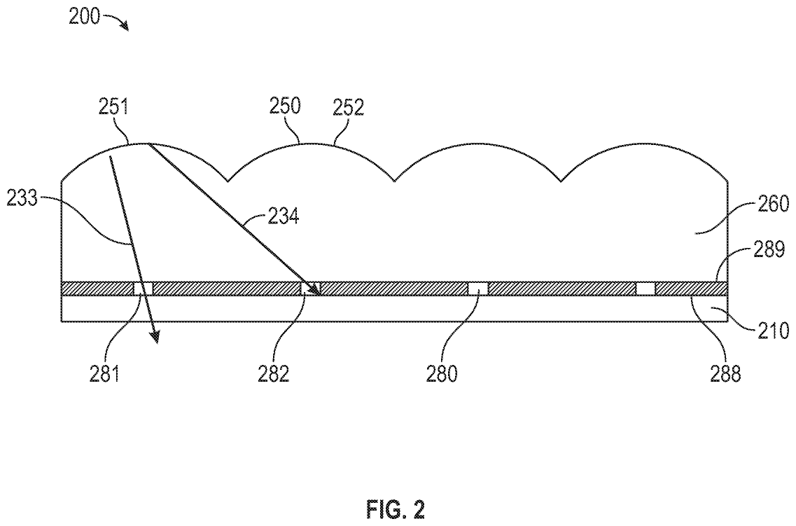

FIG. 2 is a schematic cross-sectional view of an optical element 200 including an array of microlenses 250, a pinhole mask 289 including an array of pinholes 280, and a wavelength selective filter 210. Optical element 200 may correspond to optical element 100 except for the addition of the wavelength selective filter 210. In some embodiments, the wavelength selective filter 210 is adapted to: transmit a first light ray 233 having a first wavelength and transmitted from a first microlens 251 in the first array of microlenses 250 through a first pinhole 281 in the array of pinholes 280 aligned with the first microlens 251; and attenuate a second light ray 234 having the first wavelength and transmitted from the first microlens 251 through a second pinhole 282 in the array of pinholes 280 aligned with a second microlens 252 in the first array of microlenses 250 adjacent to the first microlens 251. The first wavelength can be in a range of 350 nm to 400 nm, or 400 nm to 700 nm, or 700 nm to 2500 nm, for example. In some embodiments, the first and second light rays 233 and 234 have a same first polarization state. In some embodiments, the first and second light rays 233 and 234 are unpolarized. The filter 210 can attenuate an incident light 234 by reducing the amount of the incident light that is transmitted through the filter 210 by absorption, reflection, or a combination thereof. In some embodiments, the filter 210, absorbs and/or reflects greater than 50% or greater than 70% of the incident light 234. In some embodiments, the filter 210 blocks the incident light 234. In some embodiments, the filter 210 is or includes a wavelength selective mirror (e.g., reflecting at least 70% of normally incident light in a reflection band for each of two orthogonal polarization states). In some embodiments, the filter 210 is or includes a wavelength selective reflective polarizer (e.g., reflecting at least 70% of normally incident light in the wavelength range of the reflection band for a first polarization state and transmitting at least 60% of normally incident light in the same wavelength range for an orthogonal second polarization state). In some embodiments, filter 210 has a transmittance of greater than 70% or greater than 80% for normally incident light having the first wavelength and a first polarization state. In some embodiments, filter 210 has a transmittance of less than 30% or less than 20% for light incident at 60 degrees to normal and having the first wavelength and the first polarization state. In some embodiments, filter 210 has a transmittance of greater than 70% or greater than 80% for normally incident unpolarized light having the first wavelength. In some embodiments, filter 210 has a transmittance of less than 30% or less than 20% for unpolarized light incident at 60 degrees to normal and having the first wavelength.

In some embodiments, the wavelength selective filter 210 includes an interference filter, an absorptive filter, or a combination thereof. For example, the wavelength selective filter 210 may include an interference filter which may be or include a multilayer optical film as described further elsewhere herein. In some embodiments, a first layer 260 having opposing first and second major surfaces includes the a array of microlenses 250 on the first major surface and a second layer 288 includes the pinhole mask 289 including the array of pinholes 280 (e.g., pinholes in a substantially optically opaque material or pinholes in a wavelength selective filter) with each pinhole in the array of pinholes 280 disposed to receive light from a corresponding microlens in the array of microlenses 250. The wavelength selective filter 210 may be disposed at other locations in the optical element 200 such that the filter 210 is in optical communication with the array of microlenses 250 and the array of pinholes 280. The term “optical communication” as applied to two objects means that light can be transmitted from one to the other either directly or indirectly using optical methods (for example, reflection, diffraction, refraction). In some embodiments, the filter 210, which may be or include an interference filter, is disposed adjacent at least one of the first and second layers 260 and 268 and has, at normal incidence, a pass band extending over a predetermined wavelength range and having a long wavelength band edge wavelength in a visible or near-infrared wavelength range (e.g., the long wavelength band edge wavelength may be in a range of 400 nm to 2500 nm, or in a range of 500 nm to 2000 nm, or in a range of 600 nm to 1500 nm). Suitable interference filters may include alternating inorganic layers, alternating organic layers (e.g., isotropic or birefringent polymeric multilayer optical films), or alternating organic and inorganic layers.

In some embodiments, an optical element includes a wavelength selective filter that includes more than one component which may be immediately adjacent one another or may be separated by one or more layers. For example, the wavelength selective filter may include an optically absorptive layer and a multilayer optical film which may be immediately adjacent to the absorptive layer or separated by one or more layers. In some embodiments, the first layer 260 is the optically absorptive layer and in some embodiments, the optically absorptive layer is an additional layer disposed adjacent the array of microlenses opposite the first layer 260. The multilayer optical film may be disposed adjacent the absorptive layer and/or on either side of the first layer 260.

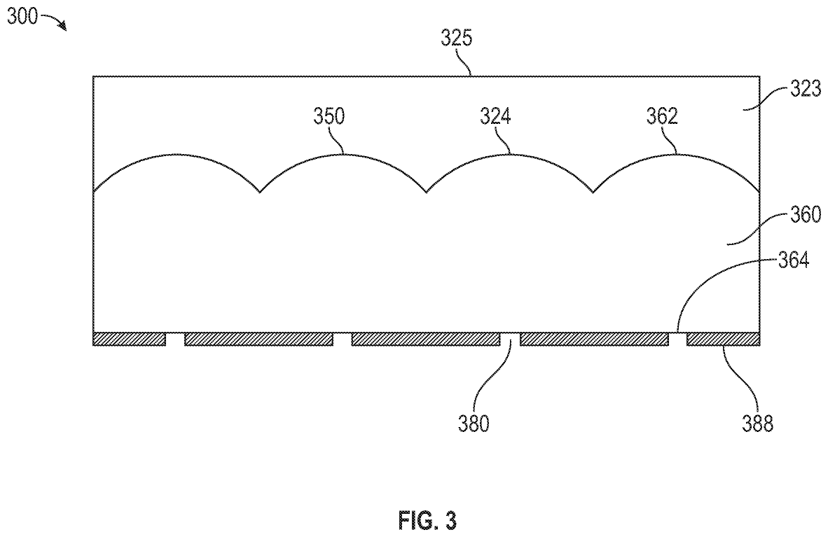

FIG. 3 is a schematic cross-sectional view of an optical element 300 including a first layer 360 having first and second major surfaces 362 and 364 where the first major surface includes an array of microlenses 350, an array of pinholes 380 in a second layer 388, and a third layer 323 which is optionally omitted in some embodiments. Optical element 300 may correspond to optical element 100 except for the addition of the third layer 323. A wavelength selective filter may be included as described for optical element 200. Third layer 323 has opposing first and second major surfaces 324 and 325. The first major surface 324 of the third layer 323 is disposed on the first major surface 362 of the first layer 360. The first major surface 324 but not the second major surface 325 of the third layer 323 has a shape substantially conforming to the first major surface 362 of the first layer 360. In some embodiments, at least one of the first layer 360 or optional third layer 323 includes wavelength selective absorptive material (e.g., dyes, pigments, or a combination thereof) dispersed throughout the layer and providing an absorption band having an absorption for normally incident light in a predetermined first wavelength range of at least 50%, or at least 60%, or at least 70%. The predetermined first wavelength range may be any suitable range for a given application and may include visible and/or near infrared wavelengths and/or near ultraviolet wavelengths. In some embodiments, the optional third layer 323 is included and each of the first and third layers 360 and 323 includes the wavelength selective absorptive material. In some embodiments, the third 323 and not the first 360 layer includes the wavelength selective absorptive material. In some embodiments, the first 360 and not the third 323 layer includes the wavelength selective absorptive material.

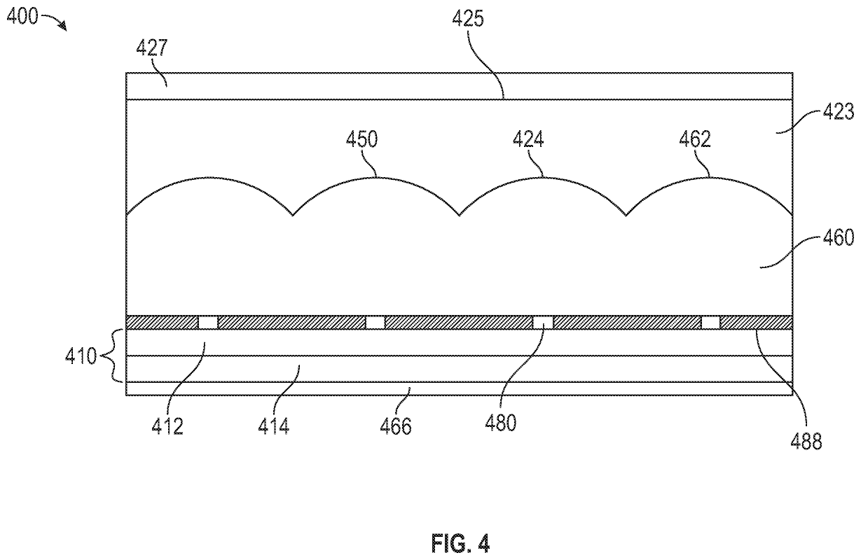

FIG. 4 is a schematic cross-sectional view of an optical element 400 including a first layer 460 having a major surface 462 including an array of microlenses 450, an array of pinholes 480 in a second layer 488, a third layer 423, an adhesive layer (e.g., an optically clear adhesive layer) disposed on the third layer 434 opposite the first layer 460, an optical filter 410 (e.g., a wavelength selective filter) disposed on the second layer 488, and a barrier layer 466 disposed on the optical filter 410. Elements 480, 488, 460, 450, 424, 425, 462, and 423 may be as described for elements 380, 388, 360, 350, 324, 325, 362, and 323, respectively. Barrier layer 466 can be any suitable type of barrier layer. Exemplary barrier layers are described further elsewhere herein. In some embodiments, the third layer 423 is a low-index layer having a refractive index of no more than 1.3 (e.g., in a range of 1.1 to 1.3) and is disposed on and has a major surface 424 substantially conforming to the first major surface 462 of the first layer 460. Refractive index refers to the refractive index at 633 nm unless indicated otherwise. Layers having a refractive index of no more than 1.3 may be nanovoided layers as described in U.S. Pat. Appl. Publ. No. 2013/0011608 (Wolk et al.) and 2013/0235614 (Wolk et al.), for example.

In some embodiments, the optical filter 410 includes two filters 412 and 414 where one of the two filters 412 and 414 is an absorptive filter and the other is an interference filter (e.g., multilayer optical film having alternating interference layers). The absorptive filter typically has an absorption band which does not substantially shift with angle of incidence, while the interference filter typically has a transmission band and/or reflection band that shifts with increasing angle of incidence. Utilizing a combination of an absorptive filter and an interference filter can result in reduced cross-talk (light from one microlens incident on a pinhole aligned with a different microlens) due to the relative shift of the band edges of the filters. Optical filters using a multilayer optical film interference filter and an absorbing optical filter are described in PCT Pub. No. WO 2018/013363 (Wheatley et al.) and WO 2017/213911 (Wheatley et al.).

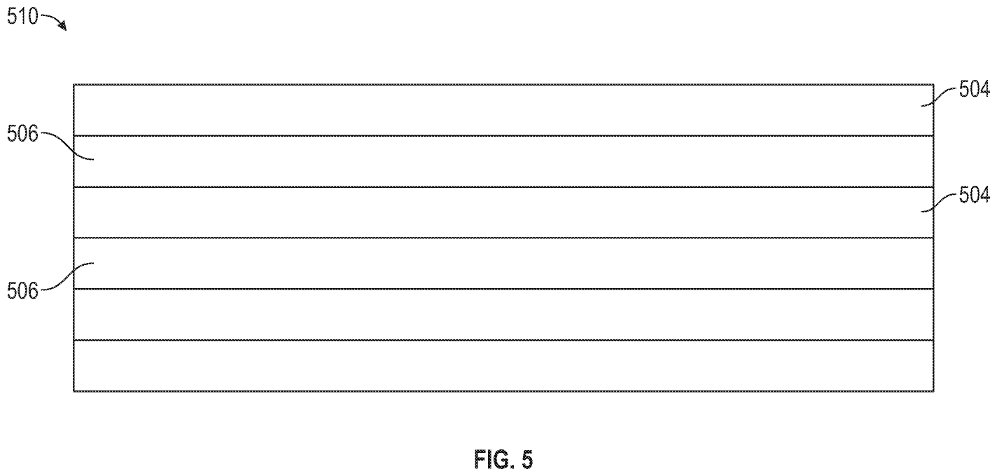

FIG. 5 is a schematic cross-sectional view of an interference filter 510 including alternating first and second layers 504 and 506. In some embodiments, interference filter 510 is a multilayer optical film and the alternating first and second layers 504 and 506 are alternating polymeric layers where at least one of the first and second layers 504 and 506 are oriented birefringent polymeric layers. In some embodiments, the interference filter 510 is a wavelength selective mirror or a wavelength selective reflective polarizer. Such polymeric filters (e.g., mirrors or reflective polarizers) are generally described in U.S. Pat. No. 5,882,774 (Jonza et al.); U.S. Pat. No. 5,962,114 (Jonza et al.); U.S. Pat. No. 5,965,247 (Jonza et. al.); U.S. Pat. No. 6,939,499 (Merrill et al.); U.S. Pat. No. 6,916,440 (Jackson et al.); U.S. Pat. No. 6,949,212 (Merrill et al.); and U.S. Pat. No. 6,936,209 (Jackson et al.); for example. In brief summary, a polymeric multilayer optical film can be made by coextruding a plurality of alternating polymeric layers (e.g., hundreds of layers), uniaxially or substantially uniaxially stretching the extruded film (e.g., in a linear or parabolic tenter) to orient the film in the case of a polarizer or biaxially stretching the film to orient the film in the case of a mirror.

A multilayer optical film can include skin layer(s) at the outer surface(s) to protect the alternating interference layers. In some embodiments, absorptive dye(s) and/or pigment(s) are included in the skin layer(s), for example, to provide the absorptive filter. In other embodiments, the absorptive layer is formed separately and attached to the multilayer optical film or disposed elsewhere in an optical path through the optical element.

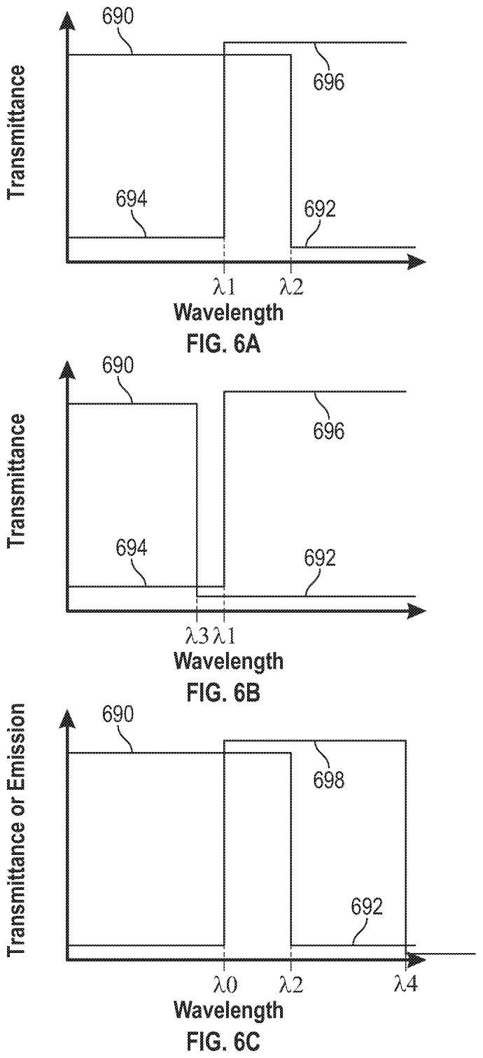

FIG. 6A is a schematic plot of transmittance at normal incidence verses wavelength for an absorptive filter having an absorption band 694 having a long wavelength band edge wavelength of λ1 and having a pass band or transmission band 696, and for a multilayer optical film having a pass band or transmission band 690 having a long wavelength band edge λ2 and having a reflection band 692. A long wavelength band edge is the longer wavelength band edge or right band edge of a band which may also have a short wavelength band edge or left band edge at a lower wavelength. FIG. 6B is a schematic plot of transmittance verses wavelength at an oblique (e.g., 45 degrees or 60 degrees to normal) angle of incidence for the absorptive filter and multilayer optical film of FIG. 6A. The long wavelength band edge of the absorption band 694 is still at the wavelength λ1 while the long wavelength band edge of the transmission band 690 has shifted from λ2 to λ3. In some embodiments, the long wavelength band edge λ1 of the absorption band 694 differs from the long wavelength band edge λ2 of the pass band 690 at normal incidence by no more than 200 nm (i.e., |λ1−λ2|≤200 nm). In some embodiments, for at least one oblique angle of incidence, λ3<λ1. In some embodiments, the multilayer optical film has the reflection band 692 for one polarization state and not for an orthogonal polarization state. In other embodiments, the multilayer optical film has the reflection band 692 for each of two orthogonal polarization states.

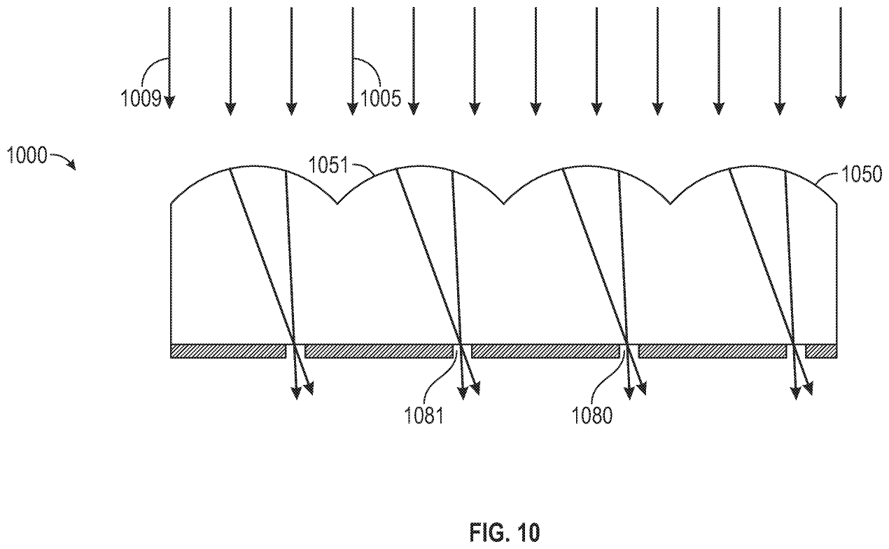

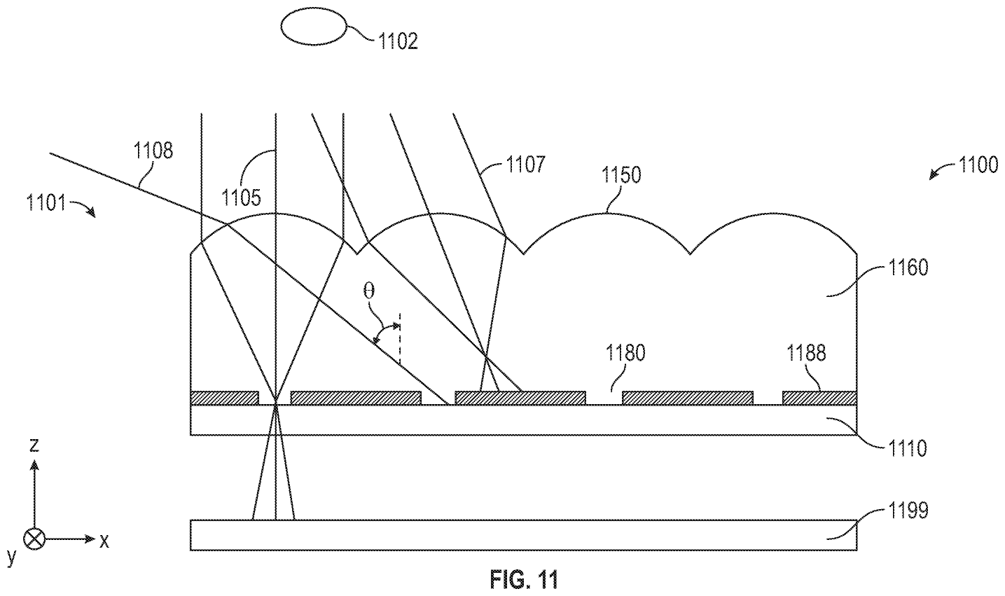

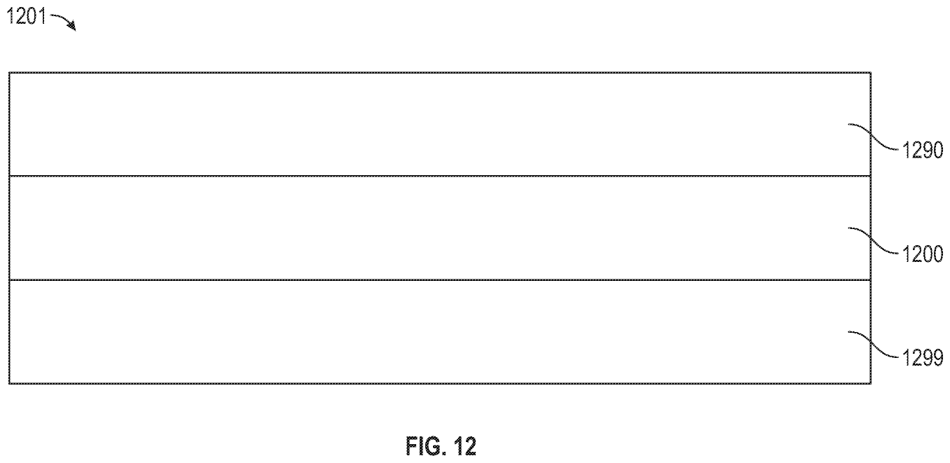

In some embodiments, an optical assembly includes an optical element of the present description and further includes a light source in optical communication with the optical element. For example, in FIG. 12, the display 1290 and the optical element 1200 may be considered to be an optical assembly where the display 1290 is or includes the light source. As another example, the light source 1102 with the optical element 1100 of FIG. 11 can be considered to be an optical assembly. FIG. 6C schematically illustrates an emission spectrum 698 of a light source superimposed on the transmittance of a multilayer optical film at normal incidence. In some embodiments, the emission spectrum has a short wavelength band edge wavelength λ0 differing from the long wavelength band edge wavelength λ2 of the pass band of the multilayer optical film at normal incidence by no more than 200 nm (i.e., |λ0−λ2|≤200 nm). In some embodiments, for at least one oblique angle of incidence λ3<λ0. In some embodiments, the emission spectrum 698 of the light source has a long wavelength band edge wavelength λ4. In some embodiments, λ4−λ0 is less than 100 nm, or less than 50 nm, or in a range of 10 nm to 45 nm. In some embodiments, the light source has an emission spectrum having a full width at half maximum of λ4−λ0.

A band edge wavelength can be taken to be the wavelength where the relevant quantity (e.g., transmittance, reflectance, absorbance, emission) is halfway between its baseline value on either side of the band edge.

An optical element may include any suitable number of arrays of microlenses in an optical path through the optical element. In some embodiments, an optical element includes only a first array of microlenses. In other embodiments, an optical element includes a plurality of arrays of microlenses and includes an array of pinholes aligned with each array of microlenses in the plurality of arrays of microlenses. In some embodiments, the plurality of arrays of microlenses includes a first array of microlenses and a second array of microlenses with the array of pinholes disposed between the first and second arrays of microlenses.

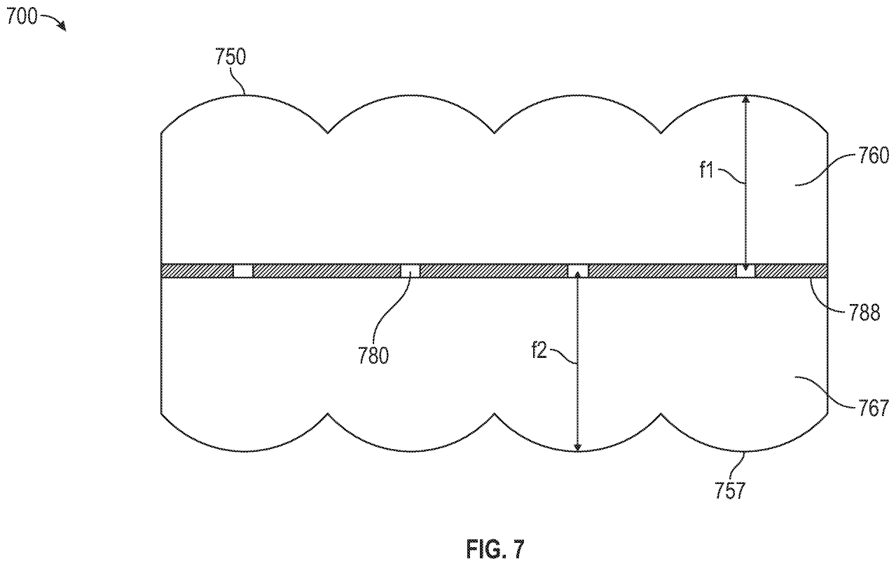

FIG. 7 is a schematic cross-sectional view of an optical element 700 including a first microlens layer 760 including a first array of microlenses 750, a second microlens layer 767 including a second array of microlenses 757, and a pinhole mask 788 including an array of pinholes 780. The pinhole mask 788 is disposed between the first and second microlens layers 760 and 757. The pinhole mask 788 may include a layer of substantially opaque material or may include a wavelength selective layer as described further elsewhere herein.

In some embodiments, each microlens in the first array of microlenses has a first focal length f1 and each microlens in the second array of microlenses has a second focal length f2. In some embodiments f2 is substantially equal (e.g., to within 5%) to f1. In some embodiments, f2 is different (e.g., greater than 5% or greater than 10% different) from f1.

In some embodiments, each microlens in an array of microlenses has a focal point at (e.g., in the pinhole or at a top or bottom of the pinhole) a corresponding pinhole in the array of pinholes. In some embodiments, first and second arrays of microlenses are included and each microlens in each of the first and second arrays of microlenses has a focal point at a corresponding pinhole in the array of pinholes. For example, f1 and f2 may be the same and the thickness of the microlens layers 760 and 767 may be the same, or f2 may be greater than f1 and the thickness of layer 767 may be thicker than the thickness of layer 760 so that each lens has a focal point is at a corresponding pinhole.

The optical element 700 may include a wavelength selective optical filter as described further elsewhere herein. The optical filter can be included anywhere in the optical path. For example, the optical filter can be disposed at an outer major surface (e.g., adjacent either array of microlenses 750 or 757), or the optical filter can be disposed between the first and second microlens layers 760 and 767. In some embodiments, the optical filter includes two or more filters (e.g., an absorptive filter and an interference filter). The two or more filters can be immediately adjacent one another or can be disposed at different locations in the optical path (e.g., one adjacent one array of microlenses and the other adjacent the other array of microlenses or between the two microlens layers).

In some embodiments, the arrays of microlenses and pinholes are aligned with optical axes of a microlens in the array 750 and a microlens in the array 757 coincident with one another and passing through a corresponding pinhole in the array of pinholes 780. In some embodiments, the arrays of microlenses and pinholes are aligned with an offset so that the optical element 700 is adapted to transmit obliquely incident light (light incident on the optical element 700 along a direction oblique to a major plane (e.g., plane of the pinhole mask 788) of the optical element 700).

An array of pinholes can be considered to be aligned with an array of microlenses if each pinhole in the array of pinholes is disposed to receive light from a corresponding microlens (e.g., incident on the microlens from a fixed direction) in the array of microlenses. In some embodiments, light from a fixed direction is directed by each microlens in the array of microlens primarily to a corresponding pinhole in the array of pinholes (e.g., greater than 50%, or greater than 70% of light incident on the microlens, and not absorbed by any optional absorptive material between the microlens surface and the pinhole mask, is transmitted to the corresponding pinhole). In some embodiments, each lens in the array of microlenses has an optical axis and each pinhole in the array of pinholes is disposed along the optical axis of the corresponding microlens. In some embodiments, each microlens is symmetric (e.g., about an optical axis passing through a center of the microlens) and each pinhole is disposed directly under a center of the microlens. In some embodiments, the array of microlens is disposed on a first periodic lattice and the array of pinholes is disposed on a second periodic lattice having a same symmetry, pitch and orientation as the first periodic lattice. In some embodiments, the second periodic lattice is laterally offset from the first periodic lattice by a fixed predetermined distance along a predetermined direction.

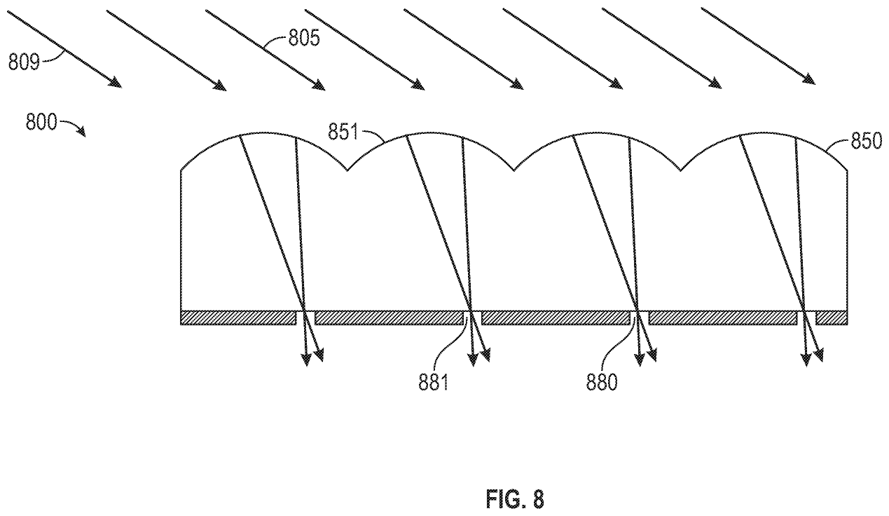

FIG. 8 is a schematic cross-sectional view of optical element 800 including an array of microlenses 850 and an array of pinholes 880. Light 805 is incident on the array of microlenses 850 along a fixed predetermined direction 809. Each microlens 851 in the array of microlenses 850 directs light 805 primarily to a corresponding pinhole 881 in the array of pinholes 880. Each pinhole in the array of pinholes 880 is aligned with a microlens in the array of microlenses 850. The pinholes 880 are offset laterally from centers of the microlenses 850 by a fixed distance. In some embodiments, the microlenses 850 are symmetric lenses.

FIG. 9 is a schematic cross-sectional view of optical element 900 including an array of asymmetric microlenses 950 and an array of pinholes 980. Light 905 is incident on the array of microlenses 950 along a fixed predetermined direction 909. Each microlens 951 in the array of microlenses 950 directs light 905 primarily to a corresponding pinhole 981 in the array of pinholes 980. Each pinhole in the array of pinholes 980 is aligned with a microlens in the array of microlenses 950. The pinholes 980 may be disposed directly under centers of the microlenses 950.

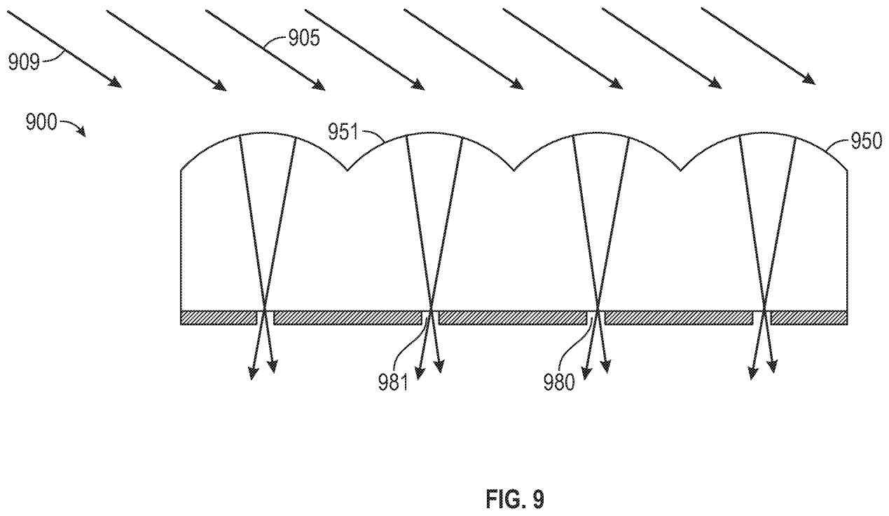

FIG. 10 is a schematic cross-sectional view of optical element 1000 including an array of microlenses 1050 and an array of pinholes 1080. Light 1005 is incident (e.g., normally incident) on the array of microlenses 1050 along a fixed predetermined direction 1009. Each microlens 1051 in the array of microlenses 1050 directs light 1005 primarily to a corresponding pinhole 1081 in the array of pinholes 1080. Each pinhole in the array of pinholes 1080 is aligned with a microlens in the array of microlenses 1050. The pinholes 1080 may be offset laterally from the centers of the microlenses 1050 by a fixed distance and the microlenses 1050 may be asymmetric lenses.

In some embodiments, an electronic device includes an optical sensor and an optical element of the present description disposed adjacent the optical sensor. FIG. 11 is a schematic cross-sectional view of an electronic device 1101 including a sensor 1199 and an optical element 1100 including a first layer 1160 having a major surface including an array of microlenses 1150, a second layer 1188 which is a pinhole mask layer including an array of pinholes 1180 (e.g., in a substantially optically opaque material or in a wavelength selective layer), and an optical filter 1110. Each pinhole in the array of pinholes 1180 is disposed to receive light from a corresponding microlens in the allay of microlenses 1150. The optical filter 1110 may be a multilayer optical film having a pass band extending over a predetermined wavelength range and having a long wavelength band edge wavelength at normal incidence in a visible or near-infrared wavelength range as described further elsewhere herein. The optical filter may be attached to the second layer 1188 through an adhesive layer, for example, and/or may be attached to the sensor 1199 through an adhesive layer, for example.

Light rays 1105, which are incident on the device 1101 in a direction approximately normal to the sensor 1199 (e.g., approximately normal to the x-y plane referring to the x-y-z coordinate system depicted in FIG. 11), are transmitted through a microlens, a corresponding pinhole, and the filter 1110 to the sensor 1199. Light rays 1107, which are obliquely incident on the device 1101, are blocked by the second layer 1188. Light ray 1108, which is incident on the device 1101 at a higher incidence angle (angle to z-direction) than light rays 1107, passes through a microlens to a pinhole aligned with an adjacent microlens and is blocked by filter 1110. In some embodiments, the array of microlenses 1150 is immersed in an adhesive layer, for example, and this reduces the index contrast across the microlenses which would make light rays such as light ray 1108 problematic for many applications if the light rays were not blocked by optical filter 1110 or another wavelength selective layer of optical element 1100. Light ray 1108 is incident on filter 1110 at an angle of incidence of 0. In some embodiments, the filter 1110 includes an interference filter having a pass band with a long wavelength band edge wavelength that shifts to sufficiently small wavelengths for an angle of incidence of 0 that the light ray 1108 is outside the pass band and is blocked.

In some embodiments, the device 1101 further includes at least one light source or at least one light source array. The light source(s) may include one or more light emitting diodes (LEDs), one or more lasers, or one or more laser diodes (e.g., vertical cavity surface emitting laser (VCSEL), for example. In some embodiments, the at least one light source includes a first light source 1102. In some embodiments, the light source 1102 has an emission spectrum having a full width at half maximum of less than 100 nm, or less than 50 nm, or in a range of 10 nm to 45 nm, for example. In some embodiments, the light source 1102 is at least partially collimated. Utilizing an at least partially collimated light source can result in reduced cross-talk (light from one microlens incident on a pinhole aligned with a different microlens), for example.

The device 1101 can be used for a variety of different applications. For example, biometric, bioanalytic and molecular analysis devices utilizing optical sensors are known in the art and an optical element of the present description can be used in such devices. In some embodiments, the device 1101 is a biometric device (e.g., detects fingerprints), a bioanalytic device (e.g., optically determines hemoglobin concentration), and/or a molecular analysis device (e.g., optically determines blood glucose levels).

In some embodiments, the electronic device 1101 further includes a display with the optical element 1100 disposed between the display and the optical sensor 1199.

FIG. 12 is a schematic illustration of an electronic display device 1201 including a display or display panel 1290, an optical sensor 1299, and an optical element 1200 disposed between the display panel 1290 and the optical sensor 1299. The optical element 1200 may be any optical element of the present description. The display panel 1290 may be a liquid crystal display (LCD) panel or an organic light emitting diode (OLED) display panel, for example. The display panel 1290 may be a semi-transparent display panel which allows at least some light to be transmitted through the display panel 1290 to the optical sensor 1299. In some embodiments, the optical sensor 1299 is configured to detect a fingerprint and the electronic display device 1201 is configured to determine if a detected fingerprint matches a fingerprint of an authorized user.

In some embodiments, an optical element includes an optical filter to reduce cross-talk. In some embodiments, a microlens array may be immersed in an optically clear adhesive layer and an optical filter may be used to reduce cross-talk resulting from the reduced refractive index contrast across the microlenses. In other embodiments, additional structures may be included in the microlens layer to provide an air gap adjacent the microlens layer when it is bonded to an adjacent layer. In this case, a low cross-talk may be achieved due to the air gap. In some embodiments, an optical filter is included to further reduce cross-talk.

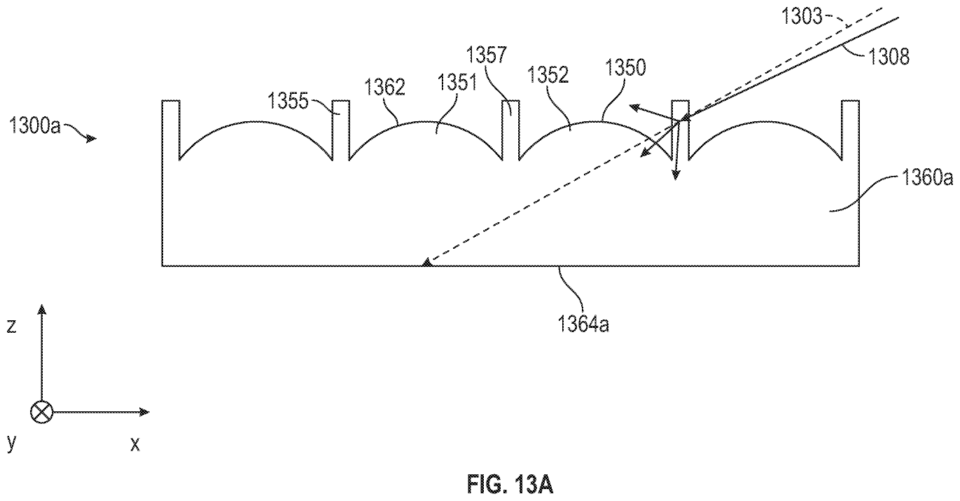

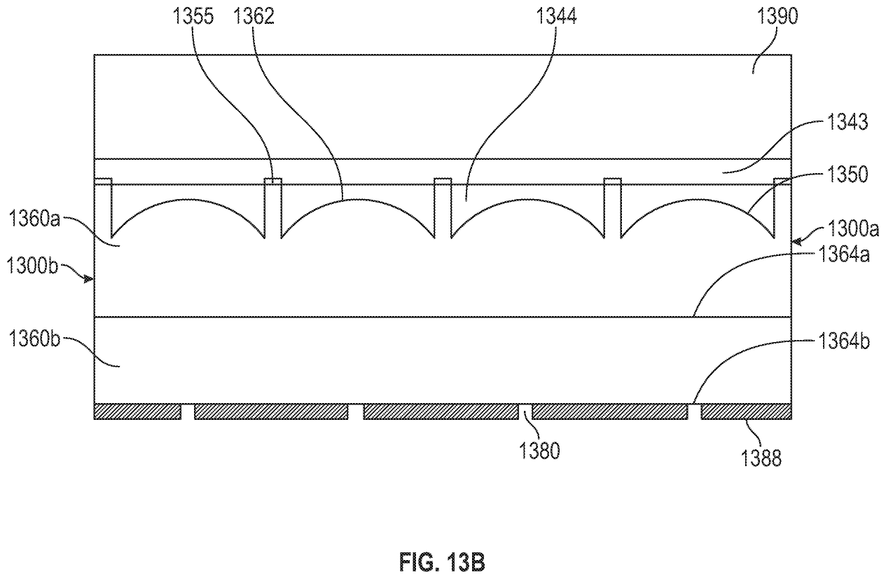

FIG. 13A is a schematic cross-sectional view of an optical element 1300a including a layer 1360a having opposing first and second major surfaces 1362 and 1364a. The first major surface 1362 includes an array of microlenses 1350 and an array of posts 1355. Each microlens in the array of microlenses 1350 is concave toward the second major surface 1364a. Each post 1357 in at least a majority of posts in the array of posts 1355 is positioned between two or more adjacent microlenses 1351 and 1352 in the array of microlenses 1350 and extends above the two or more adjacent microlenses 1351 and 1352 in a direction (e.g., z-direction, referring to the x-y-z coordinate system depicted in FIG. 13A) away from the second major surface 1364a. For example, all posts in the array of posts 1355 may be positioned between two or more adjacent microlenses in the array of microlenses 1350, or all posts except for posts near corners of the array of microlenses 1350.

In some embodiments, the layer 1360a is a monolithic layer. In other embodiments, the posts 1355 are printed onto a microlens layer so that the layer of printed posts and the microlens layer are sublayers of the layer 1360a.

In some embodiments, the array of posts 1355 is adapted to substantially diverge, diffuse, reflect, or absorb light obliquely incident on the optical element 1300a. This can be achieved by adding diffusive particles to printed posts, for example, or by suitably selecting a shape (e.g., curvature of the sides) of the posts, or by applying a coating (e.g., a reflective coating) to the posts. This can provide reduced cross-talk between neighboring microlenses. For example, an obliquely incident light ray 1303 could be transmitted through a post and through a first microlens to a pinhole in a pinhole mask (see, e.g., FIG. 13B) aligned with an adjacent microlens. If the post substantially diverges, diffuses, reflects, or absorbs the obliquely incident light, it can substantially reduce this cross-talk. This is schematically illustrated for light ray 1308 which is diffused by a post in the array of posts 1355 thereby reducing potential cross-talk.

The posts can be any objects which protrude beyond the microlenses for attachment to an adjacent layer such that the adjacent layer does not contact the microlenses. The posts can be cylindrical posts or can have a non-circular cross-section (e.g., rectangular, square, elliptical, or triangular cross-section). The posts can have a constant cross-section, or the cross-section can vary in the thickness direction (e.g., the posts can be tapered to be thinner near the top of the posts). The posts may be referred to optical decoupling structures. In some embodiments, the posts or optical decoupling structures have a tapered elliptical cross-section. For example, the optical decoupling structures can have any of the geometries of the optical decoupling structures described in U.S. Prov. Pat. Appl. No. 62/614709 filed Jan. 8, 2018 and titled “Optical Film Assemblies”. In some embodiments, the posts extend from a base of the array of microlenses. In some embodiments, at least some posts are disposed on top of at least some of the microlenses.

FIG. 13B is a schematic cross-sectional view of an optical element 1300b which includes optical element 1300a and further includes a layer 1360b. The layers 1360a and 1360b together define a first layer having a first major surface 1362 and an opposing second major surface 1364b. Optical element 1300b further includes a second layer 1388 disposed on the second major surface 1364b. The second layer 1388 is also disposed indirectly on the second major surface 1364a.

The second layer 1388 includes an array of pinholes 1380 as described further elsewhere herein. Optical element 1300b further includes an adhesive layer 1343 adjacent the first major surface 1362. Each post 1355 at least partially penetrates the adhesive layer 1343 and each microlens 1350 is entirely separated from the adhesive layer 1343 by an air gap 1344. The adhesive layer 1343 is attached to a display 1390 in the illustrated embodiment.

Optical element 1300b may further include optical filter(s) and additional array(s) of microlenses as described further elsewhere herein.

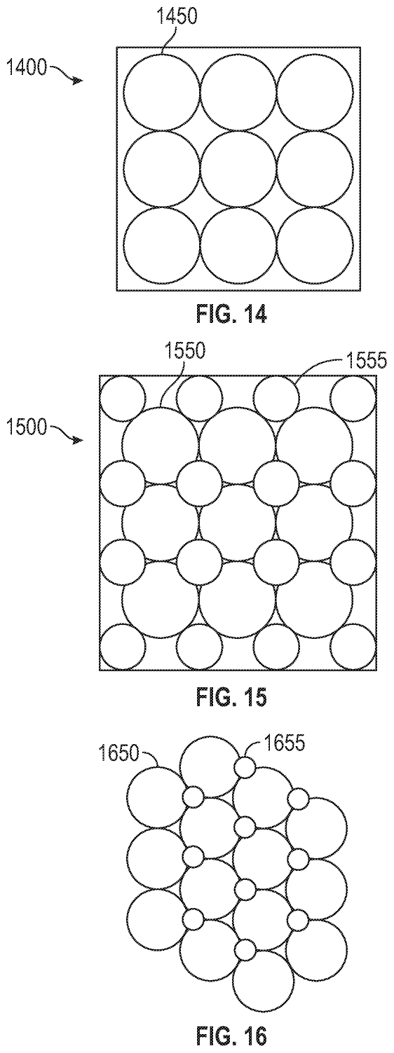

The arrays of microlenses, and posts when included, can have any suitable geometry. The array can be regular (e.g., square or hexagonal lattice) or irregular (e.g., random or pseudorandom). FIG. 14 is a schematic top view of an optical element 1400 including an array of microlenses 1450 arranged on a square lattice. FIG. 15 is a schematic top view of an optical element 1500 including an array of microlenses 1550 arranged on a square lattice and an array 1555 of posts arranged on a square lattice. FIG. 16 is a schematic top view of a portion of an array of microlenses 1650 arranged on a hexagonal lattice and a portion of an array 1655 of posts arranged on a hexagonal lattice. Examples of pseudorandom arrays of microlenses include microlenses having randomized locations that satisfy a set of constraints (e.g., a specified minimum and/or maximum center-to-center distance between adjacent microlenses) or microlenses having randomized locations within a repeating unit cell (e.g., having a repeat distance of 50 micrometers to 100 micrometers). In some embodiments, irregular arrays are useful to reduce moire and/or undesired diffraction.

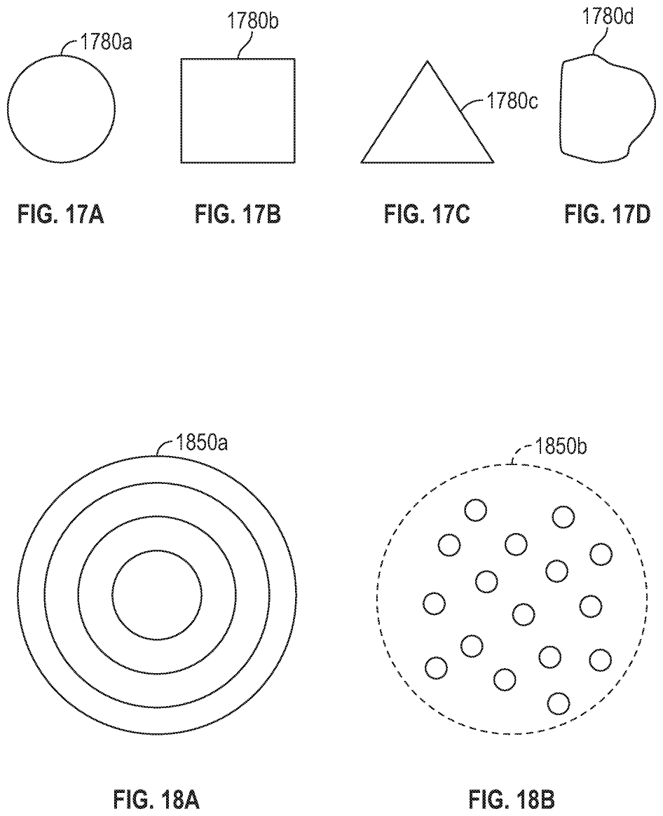

The pinholes used in any of the embodiments described herein can have any suitable shape. In some embodiments, an array of pinholes includes at least one of elliptical pinholes, circular pinholes, rectangular pinholes, square pinholes, triangular pinholes, and irregular pinholes. An array of pinholes may include any combinations of these pinhole shapes. FIGS. 17A-17D are schematic top views of pinholes 1780a-1780d. Pinhole 1780a is an elliptical pinhole which may be a circular pinhole (a circle being a special case of an ellipse) or may have a major axis larger than a minor axis, pinhole 1780b is a rectangular pinhole which may be a square pinhole (a square being a special case of a rectangle) or may have a length greater than a width, pinhole 1780c is a triangular pinhole, and pinhole 1780d is an irregular pinhole.

The microlenses used in any of the embodiments described herein can be any suitable type of microlenses. In some embodiments, an array of microlenses includes at least one of refractive lenses, diffractive lenses, metalenses (e.g., surface using nanostructures to focus light), Fresnel lenses, spherical lenses, aspherical lenses, symmetric lenses (e.g., rotationally symmetric about an optical axis), asymmetric lenses (e.g., not rotationally symmetric about an optical axis), or combinations thereof. For example, FIG. 18A is a schematic top view of a Fresnel lens 1850a and FIG. 18B is a schematic top view of a metalens 1850b.

Any of the optical elements of the present description can include a barrier layer such as barrier layer 466 depicted in FIG. 4. The barrier layer may be included at an outermost major surface and may be included so that when the optical element is attached to a moisture or oxygen sensitive device such as an OLED display the barrier helps protect the device. The barrier layer can be any suitable type of barrier layer. Useful barrier layers are described in U.S. Pat. No. 6,218,004 (Shaw et al.), U.S. Pat. No. 7,186,465 (Bright), and U.S. Pat. No. 10,199,603 (Pieper et al.), for example. In some embodiments, the barrier layer includes a smoothing polymeric layer (e.g., providing a smooth surface on which an inorganic layer can be deposited without creating defects), an inorganic layer disposed on the smoothing polymeric layer, and a polymeric protective layer disposed on the inorganic layer. In some embodiments, the barrier layer includes a plurality of inorganic layers and polymeric protective layers.

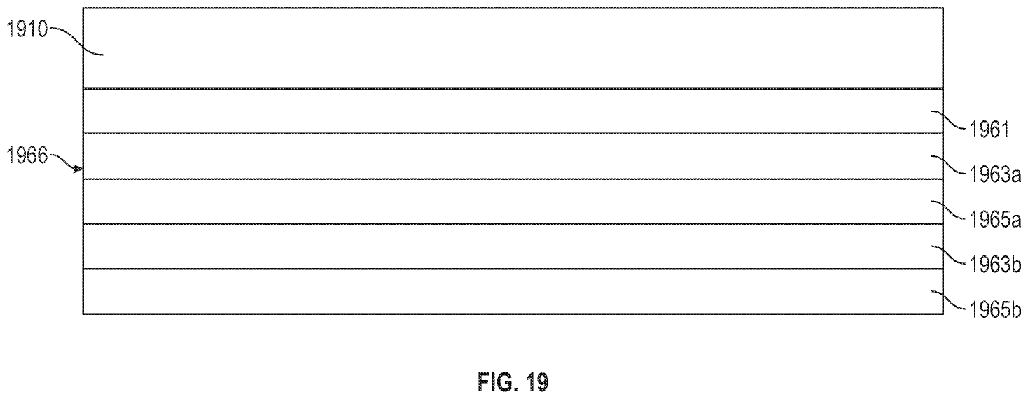

FIG. 19 is a schematic illustration of a barrier layer 1966 which may correspond to barrier layer 466, for example, and which is disposed on a layer 1910 which may be an optical filter, for example. The barrier layer 1966 includes a smoothing polymeric layer 1961, an inorganic layer 1963a disposed on the smoothing polymeric layer 1961, and a polymeric protective layer 1965a disposed on the inorganic layer 1963a. In the illustrated embodiment, the barrier layer 1966 includes a plurality of inorganic layers 1963a and 1963b and a plurality of polymeric protective layers 1965a and 1965b.

In some embodiments, an optical element includes a wavelength selective filter including an array of pinholes where the wavelength selective filter is a polymeric multilayer optical film and the array of pinholes is an array of optical pinholes. In some embodiments, the multilayer optical film extends continuously across the optical pinholes and has reduced birefringence in the optical pinholes relative to adjacent regions of the optical film.

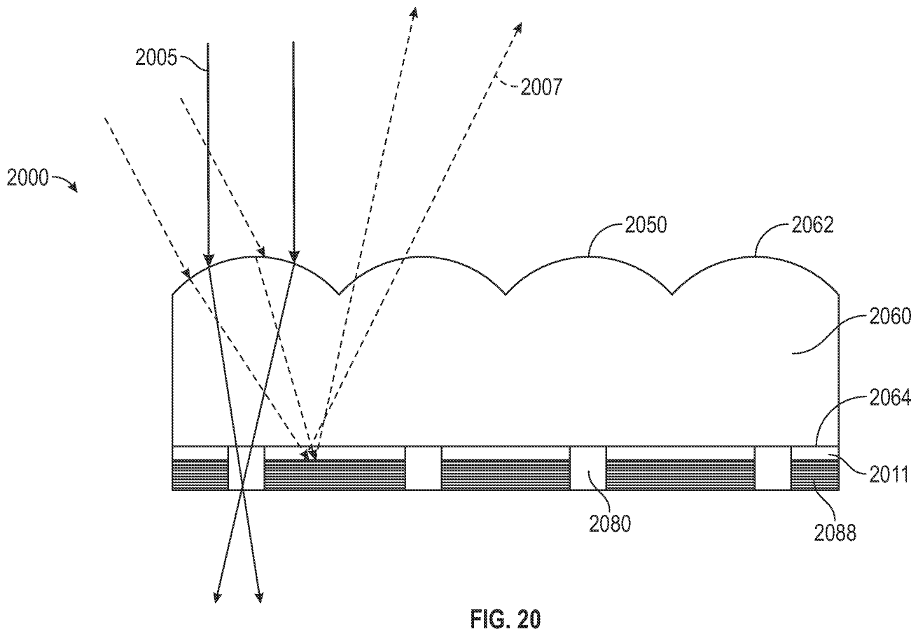

FIG. 20 is a schematic cross-sectional view of an optical element 2000 including a first array of microlenses 2050, a wavelength selective layer 2088 including an array of pinholes in or through the wavelength selective layer 2088, where each pinhole in the array of pinholes 2088 is aligned with a microlens in the first array of microlenses 2050. A first layer 2060 includes opposing first and second major surfaces 2062 and 2064 where the first major surface 2062 includes the first array of microlenses 2050. In the illustrated embodiment, the wavelength selective layer 2088 is a multilayer optical film. In some embodiments, for at least one polarization state, regions of the wavelength selective layer between adjacent pinholes transmit at least 60% of normally incident light in a predetermined first wavelength range and blocks at least 60% of normally incident light in a predetermined second wavelength range. Approximately normally incident light rays 2005 are transmitted through a microlens and a pinhole, while obliquely incident light rays 2007 are reflected by the wavelength selective layer 2088.

In some embodiments, at least a majority of the pinholes 2080 (e.g., all of the pinholes 2080) are optical pinholes. In some embodiments, the wavelength selective layer 2088 is a birefringent multilayer optical film and the optical pinholes are formed by reducing the birefringence in the film as generally described in U.S. Pat. No. 9,575,233 (Merrill et al.), for example, and the multilayer optical film is continuous across at least a majority of the pinholes. In other embodiments, at least a majority of the pinholes 2080 (e.g., all of the pinholes 2080) are physical pinholes.

The wavelength selective layer 2088 is disposed on the second major surface 2064. An optional intervening layer 2011, which may be an absorptive material, is disposed between the wavelength selective layer 2088 and the second major surface 2064. In some embodiments, the optional intervening layer 2011 is an absorption overcoat applied to the wavelength selective layer 2088 or applied to the second major surface 2064 in order to improve the absorption of the heat by a laser used to form the pinholes 2080.

In some embodiments, a method of making the optical element 200 includes providing a first layer 2060 having opposing first and second major surfaces 2062 and 2064 where the first major surface 2062 includes the first array of microlenses 2050; attaching (directly or indirectly) the wavelength selective layer 2088 to the second major surface; irradiating (e.g., with a laser) the wavelength selective layer through the first array of microlenses to form the array of pinholes. In some embodiments, the method further includes disposing an absorptive material (e.g., an absorption overcoat) between the second major surface 2064 of the first layer 2060 and the wavelength selective layer 2088. In some embodiments, the irradiating step does not substantially ablate the wavelength selective layer. In some embodiments, this results in optical pinholes 2080 where the wavelength selective layer is continuous across the pinholes 2080.

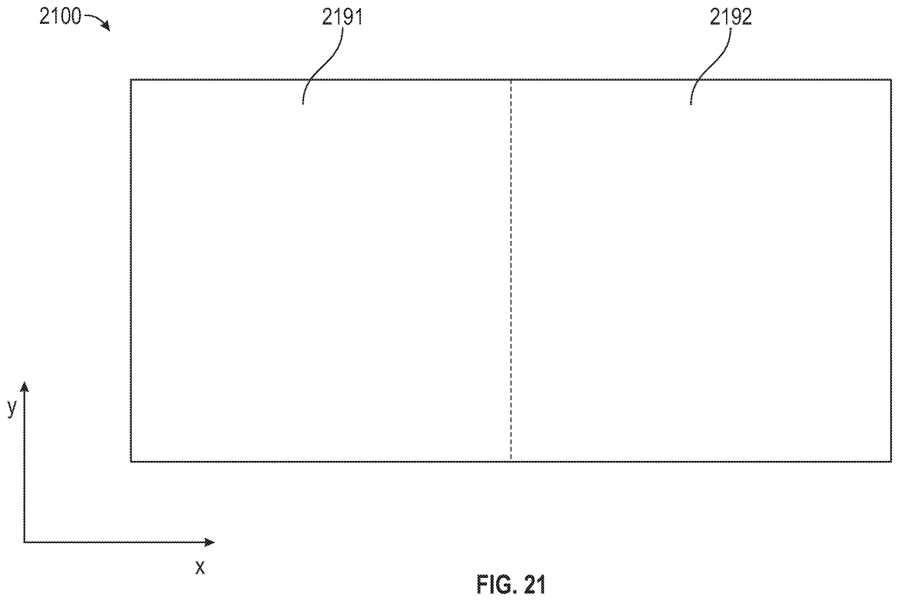

In some embodiments, at least one of the array of microlenses, the array of pinholes, or the wavelength selective filter (e.g., multilayer optical film) is spatially variant. The term spatially variant refers to a spatial variability in optical properties on a length scale substantially larger than a microlens diameter and that is distinct from a microscopic variability due to the shape of a microlens, for example. In some embodiments, a spatially variant quantity varies in a major plane (e.g., the x-y plane depicted in FIG. 21) of the optical element such than an average value of an optical property is different in first and second regions of the major plane where each of the first and second regions is at least 5 times larger than an average diameter of the microlenses in the respective first and second regions. FIG. 21 is a schematic top view of an optical element 2100 including first and second regions 2191 and 2192. In some embodiments, at least one of the array of microlenses, the array of pinholes, or the wavelength selective filter (e.g., multilayer optical film) in the first and second regions 2191 and 2192 are different. For example, the microlenses and pinholes in the first region 2191 may be arranged to transmit light incident on the first region along a first direction and the microlenses and pinholes in the second region 2192 may be arranged to transmit light incident on the second region along a different second direction. The first region 2191 may appear in cross-section as in any one of FIGS. 9-10 and the second region 2192 may appear in cross-section as in any other one of FIGS. 9-10, for example. In some embodiments, the optical element 2100 includes a multilayer optical film which is spatially variant. A spatially variant multilayer optical film can be prepared as described in U.S. Pat. No. 9,575,233 (Merrill et al.), for example.

Spatially variant optical elements are useful in senor applications, for example. In some embodiments, an electronic device includes a sensor, a light source and an optical element where external light may be transmitted through the optical element to the sensor along a first direction in one region of the optical element and transmitted from the light source through the optical element along a second direction not parallel to the first direction in another region of the optical element. The microlenses and pinholes may be arranged differently in the two regions to provide the desired optics for the different first and second directions.

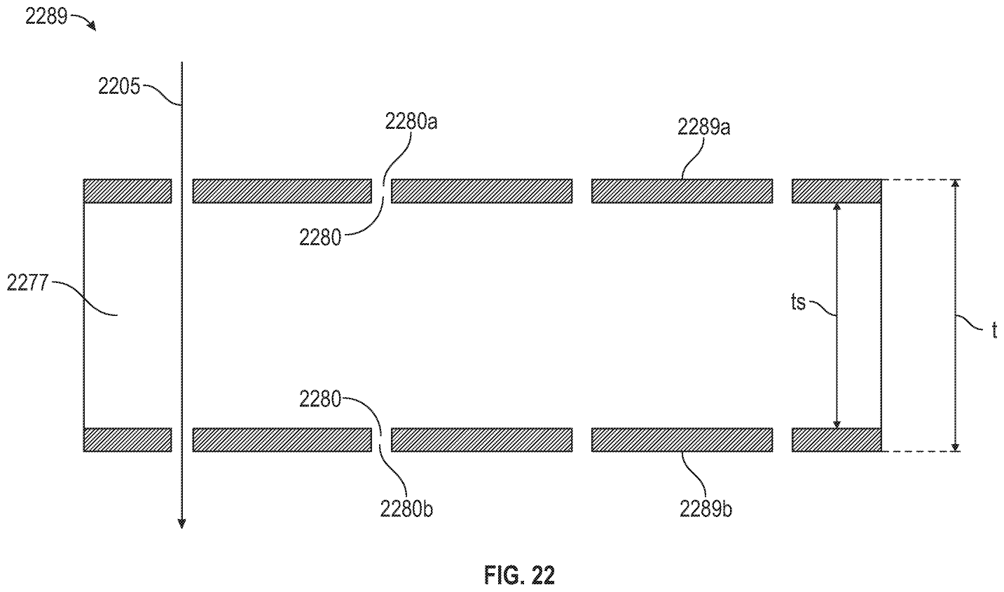

In some embodiments, and for any of the pinhole masks including an array of pinholes, or for any of the second layers including an array of pinholes, the pinhole mask or the second layer can include first and second mask layers separated by a spacer layer (and optionally additional spaced apart mask layers), where each pinhole in the array of pinholes includes a first pinhole in the first mask layer and a second pinhole in the second mask layer aligned with the first pinhole (and if any optional additional mask layer is included, aligned with pinholes of the optional additional spaced apart mask layers). This is schematically illustrated in FIG. 22 which is a schematic illustration of second layer or pinhole mask 2289 including first and second mask layers 2289a and 2289b separated by a spacer layer 2277. Each pinhole 2280 in the array of pinholes includes a first pinhole 2280a in the first mask layer 2289a and a second pinhole 2280b in the second mask layer 2289b that is aligned with the first pinhole 2280a. For example, a straight line along a predetermined direction (e.g., normal to a major plane of the spacer layer 2277) passes through the first and second pinholes 2280a and 2280b, in the illustrated embodiment, so that the array of pinholes 2280 is adapted to transmit normally incident light 2205.

Using spaced apart first and second mask layers 2289a and 2289b has been found to provide an improved reduction in crosstalk. For example, replacing the second layer 1188 of FIG. 11 with the second layer or pinhole mask 2289 can result in the light ray 1108 being blocked by the second layer or pinhole mask 2289 so that the optical filter 1110 can optionally be omitted. The first and second mask layers 2289a and 2289b are preferably sufficiently spaced apart to appreciably reduce such crosstalk. For example, in some embodiments, an optical element includes a first array of microlenses where a distance between the first array of microlenses and the first mask layer 2289a is T0 (the distance T0 of FIG. 1 corresponds to the distance between the array of microlenses 150 and the first mask layer 2289a when the second layer or pinhole mask 2289 is used in the as the second layer 188 or the pinhole mask 189), the first array of microlenses has an average center to center distance between adjacent microlenses of S0, the array of pinholes has an average pinhole diameter d, and a distance ts between the first and second mask layers 2289a and 2289b (ts is equal to the thickness of the spacer layer 2277 in the illustrated embodiment) is no less than 0.1 T0*d/S0. In some embodiments, 10 T0*d/S0≥ts≥0.1 T0*d/S0, or 8 T0*d/S0≥ts≥0.2 T0*d/S0, or 6 T0*d/S0≥ts≥0.4 T0*d/S0, 4 T0*d/S0≥ts≥0.5 T0*d/S0. In some embodiments, each of the first and second mask layers 2289a and 2289b has a thickness less than 0.2, or less than 0.1, or less than 0.05 times a thickness of the spacer layer 2277.

The second layer of pinhole mask 2289 can be formed by irradiation (e.g., laser ablation) through the microlenses, for example. It has been found that the pinholes in the first and second mask layers 2289a and 2289b can be formed in a same laser ablation step and that this improves the alignment accuracy between the first and second mask layers 2289a and 2289b compared to embodiments where the first and second mask layers 2289a and 2289b are formed separately and then laminated together with the spacer layer 2277 between the first and second mask layers 2289a and 2289b.

In some embodiments, each of the first and second mask layers 2289a and 2289b is substantially optically opaque between adjacent pinholes (e.g., the first and second mask layers 2289a and 2289b may be formed by forming pinholes in aluminum layers). In some embodiments, one or both of the first and second mask layers 2289a and 2289b are wavelength selective layers as described further elsewhere herein. In some embodiments, the spacer layer 2277 is substantially transparent. A substantially transparent layer has a transmission for normally incident unpolarized light in a predetermined wavelength range in the near-ultraviolet (e.g., less than 400 nm and at least 350 nm), visible (e.g., 400 nm to 700 nm) and/or infrared (greater than 700 nm and no more than 2500 nm) of at least 70%, or at least 80%, or at least 85%. In some embodiments, the spacer layer includes optically absorptive material. Optically absorptive material (e.g., dye(s) and/or pigment(s)) may be included to further reduce crosstalk.

The pinholes in the array of pinholes may or may not physically extend through the second layer or pinhole mask 2289. In some embodiments, for each pinhole 2280 in the array of pinholes, the first pinhole 2280a in the first mask layer 2289a and the second pinhole 2280b in the second mask layer 2289b are physical pinholes. In some embodiments, for each pinhole in the array of pinholes, a physical pinhole in the spacer layer 2277 extends between the first and second pinholes. In other embodiments, for each pinhole in the array of pinholes, no physical pinhole in the spacer layer extends between the first and second pinholes. That is, no physical pinholes are present in the spacer layer 2277 in some embodiments.

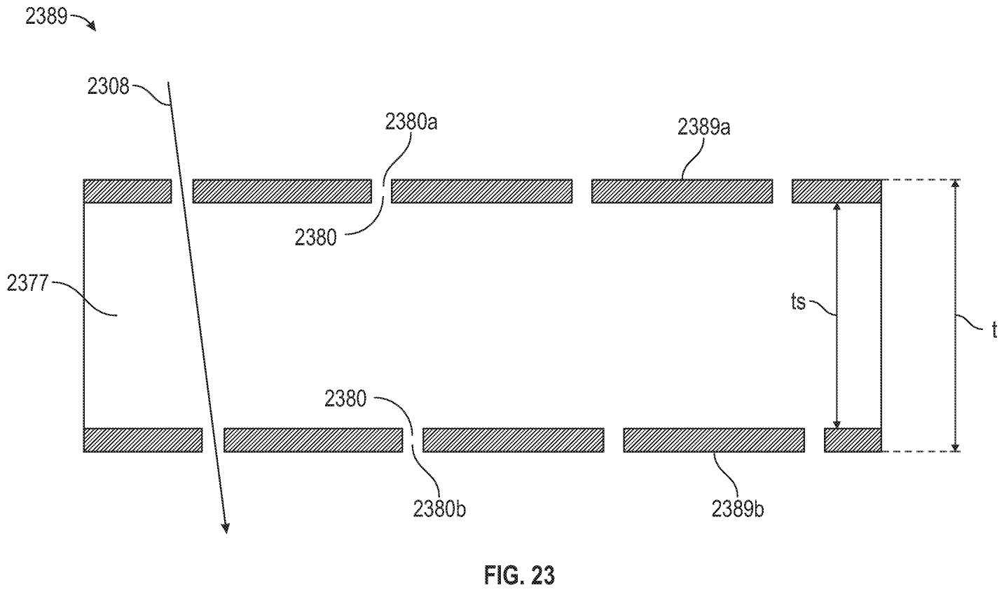

FIG. 23 is a schematic illustration of second layer or pinhole mask 2389 including first and second mask layers 2389a and 2389b separated by a spacer layer 2377. Each pinhole 2380 in the array of pinholes includes a first pinhole 2380a in the first mask layer 2389a and a second pinhole 2380b in the second mask layer 2389b that is aligned with the first pinhole 2380a. The second layer or pinhole mask 2389 may correspond to the second layer or pinhole mask 2280 except for the alignment of the first and second pinholes 2380a and 2380b. In the illustrated embodiment, a straight line along a predetermined direction (e.g., oblique to a major plane of the spacer layer 2377) passes through the first and second pinholes 2380a and 2380b, so that the array of pinholes 2380 is adapted to transmit obliquely incident light 2308. In other embodiments, a single thick pinhole layer is utilized with the pinhole angled at the predetermined oblique angle of incidence. The single layer pinhole or the pinholes through spaced apart first and second mask layers may be formed by irradiation (e.g., laser ablation) through an array of microlenses, for example, as described further elsewhere herein.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

1. An optical element comprising:
a first array of microlenses;
a pinhole mask comprising an array of pinholes, each pinhole in the array of pinholes aligned with a microlens in the first array of microlenses; and
a wavelength selective filter adapted to:
transmit a first light ray having a first wavelength and transmitted from a first microlens in the first array of microlenses through a first pinhole in the array of pinholes aligned with the first microlens; and
attenuate a second light ray having the first wavelength and transmitted from the first microlens through a second pinhole in the array of pinholes aligned with a second microlens in the first array of microlenses adjacent to the first microlens.

2. The optical element of claim 1, further comprising:
a first layer comprising opposing first and second major surfaces, the first major surface comprising the first array of microlenses, the pinhole mask disposed on the second major surface of the first layer.

3. The optical element of claim 1, further comprising a plurality of arrays of microlenses, the plurality of arrays of microlenses comprising the first array of microlenses, the array of pinholes aligned with each array of microlenses in the plurality of arrays of microlenses.

4. The optical element of claim 1, wherein the wavelength selective filter comprises a multilayer optical film having a pass band extending over a predetermined wavelength range and having a long wavelength band edge in a visible or near-infrared wavelength range.

5. The optical element of claim 1, wherein the wavelength selective filter comprises an optically absorptive filter.

6. The optical element of claim 1, wherein the first array of microlenses is adapted to transmit obliquely incident light to the array of pinholes.

7. The optical element of claim 1, further comprising a first layer comprising first and second major surfaces, the first major surface comprising the first array of microlenses and an array of posts, each post in at least a majority of posts in the array of posts positioned between two or more adjacent microlenses in the first array of microlenses and extending above the two or more adjacent microlenses in a direction away from the second major surface.

8. An optical element comprising:
a first layer having opposing first and second major surfaces, the first major surface comprising a first array of microlenses;
a second layer comprising an array of pinholes, each pinhole in the array of pinholes disposed to receive light from a corresponding microlens in the first array of microlenses; and
a multilayer optical film adjacent at least one of the first and second layers and having, at normal incidence, a pass band extending over a predetermined wavelength range and having a long wavelength band edge wavelength at normal incidence in a visible or near-infrared wavelength range.

9. The optical element of claim 8, further comprising an optically absorptive layer in optical communication with the multilayer optical film and having an absorption band with a long wavelength band edge wavelength differing from the long wavelength band edge wavelength of the pass band of the multilayer optical film at normal incidence by no more than 200 nm.

10. The optical element of claim 8, wherein the second layer comprises a wavelength selective layer, the array of pinholes comprising pinholes in or through the wavelength selective layer.

11. An optical assembly comprising the optical element of claim 8 and further comprising a light source in optical communication with the optical element, wherein the light source has an emission spectrum comprising a short wavelength band edge wavelength differing from the long wavelength band edge wavelength of the pass band of the multilayer optical film at normal incidence by no more than 200 nm.

12. An optical element comprising:
a first array of microlenses;
a wavelength selective layer comprising an array of pinholes in or through the wavelength selective layer, each pinhole in the array of pinholes aligned with a microlens in the first array of microlenses,
wherein for at least one polarization state, regions of the wavelength selective layer between adjacent pinholes transmit at least 60% of normally incident light in a predetermined first wavelength range and blocks at least 60% of normally incident light in a predetermined second wavelength range.

13. The optical element of claim 12, further comprising a first layer comprising opposing first and second major surfaces, the second major surface disposed on the wavelength selective layer, the first major surface comprising the first array of microlenses and an array of posts, each post in at least a majority of posts in the array of posts positioned between two or more adjacent microlenses in the first array of microlenses and extending above the two or more adjacent microlenses in a direction away from the second major surface.

14-15. (canceled)

16. The optical element of claim 8, wherein the first major surface further comprises an array of posts, each post in at least a majority of posts in the array of posts being positioned between two or more adjacent microlenses in the first array of microlenses and extending above the two or more adjacent microlenses in a direction away from the second major surface.
